(19) United States
(12) Patent Application Publication
(10) Pub. No.: US 2025/0324549 A1
(43) Pub. Date: Oct. 16, 2025

(54) PORTABLE TEMPERATURE-CONTROLLED FRONT-LOADED ENCLOSURE WITH OPTIMIZED SOLID-STATE COOLING SYSTEM

(71) Applicant: FAIZAN AHMED, SAN JOSE, CA (US)

(72) Inventor: FAIZAN AHMED, SAN JOSE, CA (US)

(21) Appl. No.: 19/087,549

(22) Filed: Mar. 23, 2025

Related U.S. Application Data
(63) Continuation-in-part of application No. 18/772,087, filed on Jul. 12, 2024.
Application No. 18/772,087 is a continuation-in-part of application No. 17/579,397, filed on Jan. 19, 2022.
Application No. 17/579,397 is a continuation-in-part of application No. 17/519,562, filed on Nov. 4, 2021, now abandoned.
Application No. 17/519,562 is a continuation-in-part of application No. 16/571,190, filed on Sep. 16, 2019, now abandoned.
(60) Provisional application No. 62/772,094, filed on Nov. 28, 2018.
(60) Provisional application No. 62/811,523, filed on Feb. 27, 2019.

(51) Int. Cl. H05K 7/20

(52) U.S. Cl. CPC H05K 7/20381; H05K 7/202; H05K 7/20327

(57) ABSTRACT

In one aspect, a portable temperature-controlled enclosure represents an innovative cooling solution featuring a front-loaded aluminum payload chamber designed for easy access and efficient storage. The device's core technology centers around a semiconductor chip that is uniquely mounted at a calculated angular orientation relative to the chamber wall, creating an optimized cooling pattern throughout the enclosure. The system incorporates a sophisticated closed-loop cooling mechanism that is thermally coupled to the semiconductor chip for maximum heat transfer efficiency. To ensure reliable operation in various settings, the enclosure includes a versatile power system capable of running on both standard wall power and battery power for portable use. The entire system is managed by an advanced control system that continuously monitors and maintains precise target temperatures within the front-loaded payload chamber, making it ideal for applications requiring strict temperature control.

### CLAIM OF PRIORITY

This application is a continuation in part of U.S. patent application Ser. No. 17/519,562 filed on Nov. 4, 2021. This patent application is hereby incorporated by reference in its entirety.

U.S. patent application Ser. No. 17/519,562 is a continuation of U.S. patent application Ser. No. 16/571,190 filed Sep. 16, 2019. This patent application is hereby incorporated by reference in its entirety.

U.S. patent application Ser. No. 16/571,190 is a continuation of U.S. Provisional Patent Application No. 62/811,523 filed Feb. 27, 2019. This patent application is hereby incorporated by reference in its entirety.

U.S. patent application Ser. No. 16/571,190 is a continuation of U.S. Provisional Patent Application No. 62/772,094 filed Nov. 28, 2018. This patent application is hereby incorporated by reference in its entirety.

This application is a continuation in part of U.S. patent application Ser. No. 17/394,395 filed Aug. 4, 2021. This patent application is hereby incorporated by reference in its entirety.

U.S. patent application Ser. No. 17/394,395 is a continuation of U.S. patent application Ser. No. 16/571,190 filed Sep. 16, 2019. This patent application is hereby incorporated by reference in its entirety.

### CLAIM OF PRIORITY

This application is a continuation in part of U.S. patent application Ser. No. 17/519,562 filed on Nov. 4, 2021. This patent application is hereby incorporated by reference in its entirety.

U.S. patent application Ser. No. 17/519,562 is a continuation of U.S. patent application Ser. No. 16/571,190 filed Sep. 16, 2019. This patent application is hereby incorporated by reference in its entirety.

U.S. patent application Ser. No. 16/571,190 is a continuation of U.S. Provisional Patent Application No. 62/811,523 filed Feb. 27, 2019. This patent application is hereby incorporated by reference in its entirety.

U.S. patent application Ser. No. 16/571,190 is a continuation of U.S. Provisional Patent Application No. 62/772,094 filed Nov. 28, 2018. This patent application is hereby incorporated by reference in its entirety.

This application is a continuation in part of U.S. patent application Ser. No. 17/394,395 filed Aug. 4, 2021. This patent application is hereby incorporated by reference in its entirety.

U.S. patent application Ser. No. 17/394,395 is a continuation of U.S. patent application Ser. No. 16/571,190 filed Sep. 16, 2019. This patent application is hereby incorporated by reference in its entirety.

This application claims priority to U.S. Provisional Patent Application No. 63/770,773 filed Mar. 21, 2025. This provisional patent application is hereby incorporated by reference in its entirety.

This application claims priority to U.S. Provisional Patent Application No. 63/770,785 filed Mar. 21, 2025. This provisional patent application is hereby incorporated by reference in its entirety.

This application claims priority to U.S. Provisional Patent Application No. 63/770,791 filed Mar. 21, 2025. This provisional patent application is hereby incorporated by reference in its entirety.

This application claims priority to U.S. Provisional Patent Application No. 63/770,808 filed Mar. 21, 2025. This provisional patent application is hereby incorporated by reference in its entirety.

This application claims priority to U.S. Provisional Patent Application No. 63/770,818 filed Mar. 21, 2025. This provisional patent application is hereby incorporated by reference in its entirety.

This application claims priority to U.S. Provisional Patent Application No. 63/770,850 filed Mar. 21, 2025. This provisional patent application is hereby incorporated by reference in its entirety.

This application claims priority to U.S. Provisional Patent Application No. 63/770,870 filed Mar. 21, 2025. This provisional patent application is hereby incorporated by reference in its entirety.

This application claims priority to U.S. Provisional Patent Application No. 63/770,874 filed Mar. 21, 2025. This provisional patent application is hereby incorporated by reference in its entirety.

This application claims priority to U.S. Provisional Patent Application No. 63/770,890 filed Mar. 21, 2025. This provisional patent application is hereby incorporated by reference in its entirety.

This application claims priority to U.S. Provisional Patent Application No. 63/771,222 filed Mar. 21, 2025. This provisional patent application is hereby incorporated by reference in its entirety.

This application claims priority to U.S. Provisional Patent Application No. 63/770,591 filed Mar. 20, 2025. This provisional patent application is hereby incorporated by reference in its entirety.

This application claims priority to U.S. Provisional Patent Application No. 63/770,592 filed Mar. 20, 2025. This provisional patent application is hereby incorporated by reference in its entirety.

### BACKGROUND

### Field of the Invention

### Field of the Invention

The present invention relates generally to portable temperature-controlled storage systems, and more particularly to an front-loaded enclosure utilizing solid-state cooling technology with optimized thermal management for maintaining precise temperatures during transport and storage of temperature-sensitive materials.

### Background

Temperature-sensitive materials, particularly in medical and biological applications, require precise temperature control during storage and transport. Traditional cooling systems rely on compressors, refrigerants, or ice packs that are bulky, inefficient, and unable to maintain consistent temperatures. Current portable cooling solutions face significant challenges in maintaining precise temperatures while operating on battery power.

The limitations of existing portable cooling systems are particularly evident in applications requiring extended autonomous temperature control. Traditional compressor-based systems consume significant power and are impractical for portable use, while passive cooling solutions using ice packs or phase change materials cannot maintain precise temperature control over long periods.

Additionally, existing systems often suffer from inefficient heat transfer between cooling elements and front-loaded payload chambers, leading to temperature gradients and inconsistent cooling. This technical challenge is particularly acute in compact portable systems where space constraints limit traditional heat transfer approaches.

### BRIEF SUMMARY OF THE INVENTION

In one aspect, In one aspect, a portable temperature-controlled enclosure represents an innovative cooling solution featuring a front-loaded aluminum payload chamber designed for easy access and efficient storage. The device's core technology centers around a semiconductor chip that is uniquely mounted at a calculated angular orientation relative to the chamber wall, creating an optimized cooling pattern throughout the enclosure. The system incorporates a sophisticated closed-loop cooling mechanism that is thermally coupled to the semiconductor chip for maximum heat transfer efficiency. To ensure reliable operation in various settings, the enclosure includes a versatile power system capable of running on both standard wall power and battery power for portable use. The entire system is managed by an advanced control system that continuously monitors and maintains precise target temperatures within the front-loaded payload chamber, making it ideal for applications requiring strict temperature control.

### BRIEF DESCRIPTION OF THE DRAWINGS

FIG. 1 is a top view of example embodiment of a portable temperature-controlled enclosure, according to some embodiments.

FIG. 2 is an isometric view of example embodiment of a portable temperature-controlled enclosure, according to some embodiments.

FIG. 3 is a front view of example embodiment of a portable temperature-controlled enclosure, according to some embodiments.

FIG. 4 is a side view of example embodiment of a portable temperature-controlled enclosure, according to some embodiments.

FIG. 5-8 illustrate various example views of an aluminum cooling chamber portable unit, according to some embodiments.

FIG. 5 illustrates a top-view of aluminum cooling chamber portable unit, according to some embodiments.

FIG. 6 illustrates a isometric-view of aluminum cooling chamber portable unit, according to some embodiments.

FIG. 7 illustrates a rear-view of aluminum cooling chamber portable unit, according to some embodiments.

FIG. 8 illustrates a side-view of aluminum cooling chamber portable unit, according to some embodiments.

FIG. 9 depicts an exemplary computing system that can be configured to perform any one of the processes provided herein.

FIG. 10 a view of a display integrated into a portable front-loaded temperature-controlled enclosure, according to some embodiments.

FIG. 11 illustrates a logical view of a portable front-loaded temperature-controlled enclosure, according to some embodiments.

The Figures described above are a representative set and are not an exhaustive with respect to embodying the invention.

### DESCRIPTION

Disclosed are a system, method, and article of manufacture for an portable temperature-controlled enclosure with optimized solid-state cooling system. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to ‘one embodiment,’ ‘an embodiment,’ ‘one example,’ or similar language means that a particular feature, structure, or characteristic described in connection with the embodiment is included in at least one embodiment, according to some embodiments. Thus, appearances of the phrases ‘in one embodiment,’ ‘in an embodiment,’ and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

### Definitions

Example definitions for some embodiments are now provided.

Acrylonitrile butadiene styrene (ABS) is a common plastic polymer.

High-density polyethylene (HDPE) or polyethylene high-density (PEHD) is a polyethylene thermoplastic made from petroleum.

Peltier effect is the presence of heating or cooling at an electrified junction of two different conductors. When a current is made to flow through a junction between two conductors, A and B, heat may be generated or removed at the junction. Thermoelectric cooling uses the Peltier effect to create a heat flux between the junction of two different types of materials. A Peltier cooler, heater, or thermoelectric heat pump is a solid-state active heat pump which transfers heat from one side of the device to the other, with consumption of electrical energy, depending on the direction of the current.

Phase change material (PCM) is a substance with a high heat of fusion which, melting and solidifying at a certain temperature, is capable of storing and releasing large amounts of energy. Heat is absorbed or released when the material changes from solid to liquid and vice versa. Example PCM materials can include, inter alia: organic (paraffin and nonparaffin), inorganic (salt hydrates and metallic alloys), and eutectic (mixture of two or more PCM components: organic, inorganic, and both).

Polypropylene (PP) is a thermoplastic polymer used in a wide variety of applications. It is produced via chain-growth polymerization from the monomer propylene.

Press fit or friction fit is a fastening between two parts which is achieved by friction after the parts are pushed together, rather than by any other means of fastening.

Temperature sensors can include mechanical temperature sensors, electrical temperature sensors, integrated circuit sensors, medometers, etc.

Thermoelectric effect is the direct conversion of temperature differences to electric voltage and vice versa via a thermocouple. A thermoelectric device creates voltage when there is a different temperature on each side. Conversely, when a voltage is applied to it, heat is transferred from one side to the other, creating a temperature difference. At the atomic scale, an applied temperature gradient causes charge carriers in the material to diffuse from the hot side to the cold side.

### Example Smart Refrigerator Exterior Views

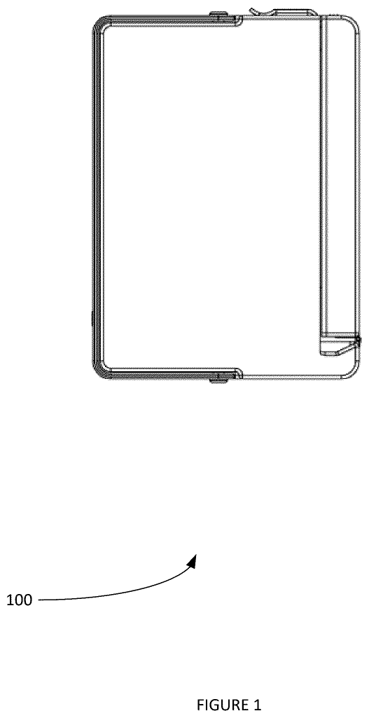

FIGS. 1-5 provide series of views of an example embodiment of a portable temperature-controlled enclosure 100, according to some embodiments. The series of views includes a set of orthographic views (e.g. top, front, side, and isometric) of the portable temperature-controlled enclosure according to one embodiment. The example embodiment of a portable temperature-controlled enclosure 100 can be a front-loaded system. Portable temperature-controlled enclosure 100 can include an optimized solid-state cooling system (e.g. see infra). Portable temperature-controlled enclosure 100 provides a portable temperature-controlled enclosure utilizing an innovative solid-state cooling system with optimized thermal management. Portable temperature-controlled enclosure 100 combines advanced thermoelectric cooling technology with sophisticated control systems to achieve superior temperature stability and extended battery operation.

Portable temperature-controlled enclosure 100 comprises several key components working in concert: a precision-engineered front-loaded payload chamber for storing temperature-sensitive materials, an optimized thermoelectric cooling system with angular mounting configuration, an integrated phase change material (PCM) chamber for thermal buffering, and a sophisticated heat dissipation system including honeycomb ventilation. These components are managed by advanced monitoring and control systems, all supported by extended battery-powered operation capability.

The front-loading portable temperature-controlled enclosure 100 represents a breakthrough in portable refrigeration technology, utilizing solid-state cooling principles to maintain precise temperature control. The front-loading portable temperature-controlled enclosure 100 distinguishes itself through the complete elimination of traditional cooling infrastructure components such as compressors, refrigerant gases, cooling coils, ice packs, or gel packs.

Example physical specifications of the front-loading portable temperature-controlled enclosure 100 are now discussed. The front-loading portable temperature-controlled enclosure 100 payload capacity, by way of example, can be a one (1) liter. The front-loading portable temperature-controlled enclosure 100 can include a front-loading design with example dimensions of 107.78 mm×119.92 mm×166.84 mm.

Access to the front-loading portable temperature-controlled enclosure 100 can be via a front-mounted lid providing full access to internal chamber. Construction of The front-loading portable temperature-controlled enclosure 100 can include precision-engineered aluminum chamber with integrated cooling system.

An example Core Cooling Technology of the front-loading portable temperature-controlled enclosure 100 is now discussed. The front-loading portable temperature-controlled enclosure 100 employs an advanced solid-state cooling mechanism based on semiconductor physics. As a cooling principle, the front-loading portable temperature-controlled enclosure 100 utilizes an electron mobility differential between semiconductor materials. By way of operation, the front-loading portable temperature-controlled enclosure 100 uses an electric current passage through dual-semiconductor junction.

The thermal energy absorption during electron transition between materials is implemented to optimizes cooling efficiency. The front-loading portable temperature-controlled enclosure 100 can achieve target temperature (2° C.) within 2-hour initialization period. The front-loading portable temperature-controlled enclosure 100 implements temperature maintenance to maintain 2-8° C. range for 72 hours without external power.

An example Thermal Management System of the internal front-loaded payload chamber incorporates a sophisticated thermal management design. As seen below, the front-loading portable temperature-controlled enclosure 100 includes a chamber construction that includes front-loaded payload 104. Here, the material composition can include a specialized heat-absorbing material combined with aluminum. The front-loading portable temperature-controlled enclosure 100 utilizes thermal spreading via an engineered aluminum structure for optimal temperature distribution. The front-loading portable temperature-controlled enclosure 100 performs heat absorption via a material matrix for thermal energy management.

The front-loading portable temperature-controlled enclosure 100 provides dynamic temperature control. Primary cooling is performed via a solid-state semiconductor chip (e.g. discussed infra). Supplementary cooling can be performed via a thermal mass buffer system. Hybrid operation between thermal mass and active cooling Response system can be used for temperature maintenance. Automated cooling bursts for temperature deviation compensation can be performed.

The front-loading portable temperature-controlled enclosure 100 can include a power and environmental adaptation power system 1102. The front-loading portable temperature-controlled enclosure 100 includes an input compatibility, by way of example of a Universal AC power (110V/220V) and an integrated charging system. Battery operation can be for 72-hour autonomous operation capability.

Optimized power consumption during steady-state operation can be obtained using bi-directional temperature control capability. For example, in a winter mode operation, the front-loading portable temperature-controlled enclosure 100 functions in extreme cold environments (−20° C. to −30° C.). Thermal management systems 1104 of the front-loading portable temperature-controlled enclosure 100 can maintains 2-8° C. in both hot and cold ambient conditions. An example environmental range enables The front-loading portable temperature-controlled enclosure 100 to be functional across extreme temperature variations.

The front-loading portable temperature-controlled enclosure 100 includes a monitoring and communication system 1106 for temperature monitoring. Real-time temperature tracking is implemented across continuous internal temperature measurement. The front-loading portable temperature-controlled enclosure 100 includes a digital display 216 for current temperature indication. The front-loading portable temperature-controlled enclosure 100 includes an alert system for temperature deviations. The front-loading portable temperature-controlled enclosure 100 includes a communication infrastructure 1108 that can include an integrated LTE module with SIM card and/or GPS location tracking capability. The front-loading portable temperature-controlled enclosure 100 can perform data transmission intervals (e.g. at 4-5 minutes. The front-loading portable temperature-controlled enclosure 100 also includes cloud connectivity for remote monitoring. A backup SD card storage system can be included for offline data logging. The front-loading portable temperature-controlled enclosure 100 includes a Data Management module 1110 for continuous temperature logging and location tracking and recording. The front-loading portable temperature-controlled enclosure 100 can also perform automated cloud data synchronization.

The front-loading portable temperature-controlled enclosure 100 includes an Operation and Performance Temperature Performance module that manages an initial cooldown (e.g. 2 hours to reach target temperature with a temperature range: 2-8° C. maintenance and operation duration of 72 hours on battery power).

A thermal interface material utilizes a high thermal conductivity compound with controlled thickness application and full surface coverage verification. Mounting pressure can be maintained at 30-40 PSI through a spring-loaded mechanism, ensuring even pressure distribution across the chip surface and compensation for thermal expansion and contraction in some example embodiments.

The front-loading configuration represents a significant advancement in portable temperature-controlled storage, combining innovative solid-state cooling technology with sophisticated thermal management and monitoring systems. The design achieves exceptional efficiency and reliability while maintaining precise temperature control across varied environmental conditions.

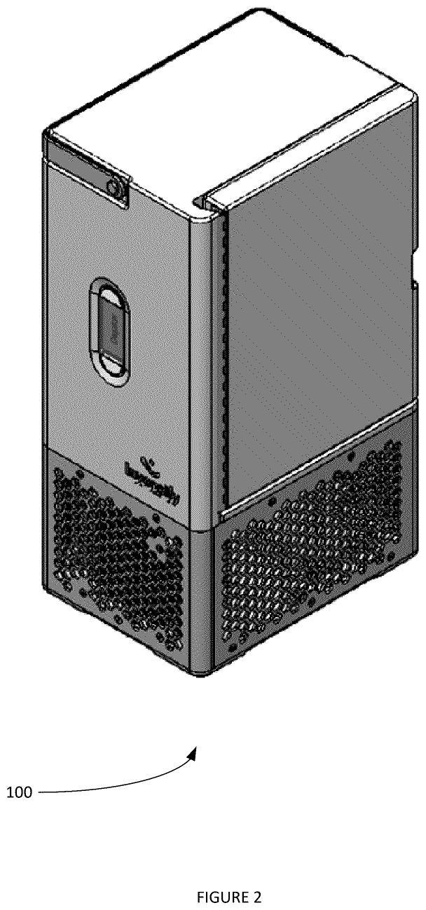

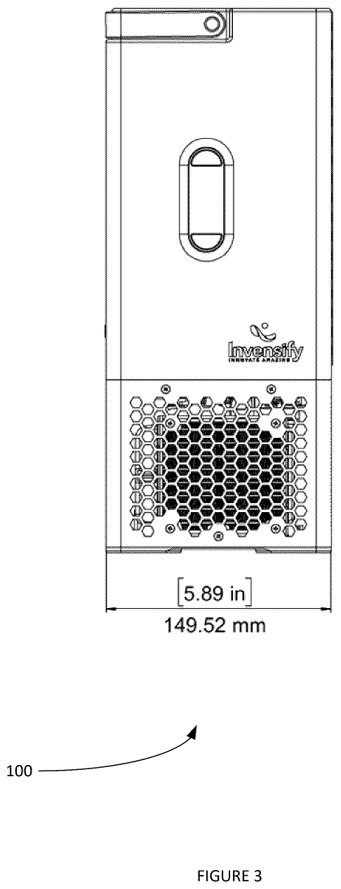

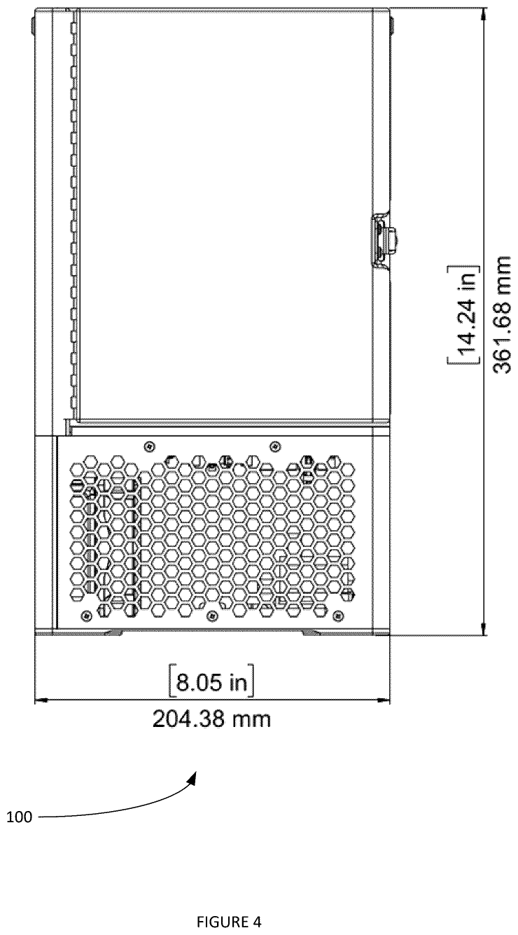

More specifically, FIG. 1 is a top view of example embodiment of a portable temperature-controlled enclosure 100, according to some embodiments. FIG. 2 is an isometric views of example embodiment of a portable temperature-controlled enclosure 100, according to some embodiments. FIG. 3 is a front view of example embodiment of a portable temperature-controlled enclosure 100, according to some embodiments. FIG. 4 is a side view of example embodiment of a portable temperature-controlled enclosure 100, according to some embodiments.

In one embodiments, portable temperature-controlled enclosure 100 can have a front-loading configuration with example front-loaded payload dimensions: 3.2″×4.1″×5.5″. An example front opening capacity can be one (1) liter. Overall dimensions, by way of example, can be 107.78 mm×119.92 mm×166.84 mm. Portable temperature-controlled enclosure 100 provides a front access lid for front-loaded payload (e.g. medications, etc.) insertion.

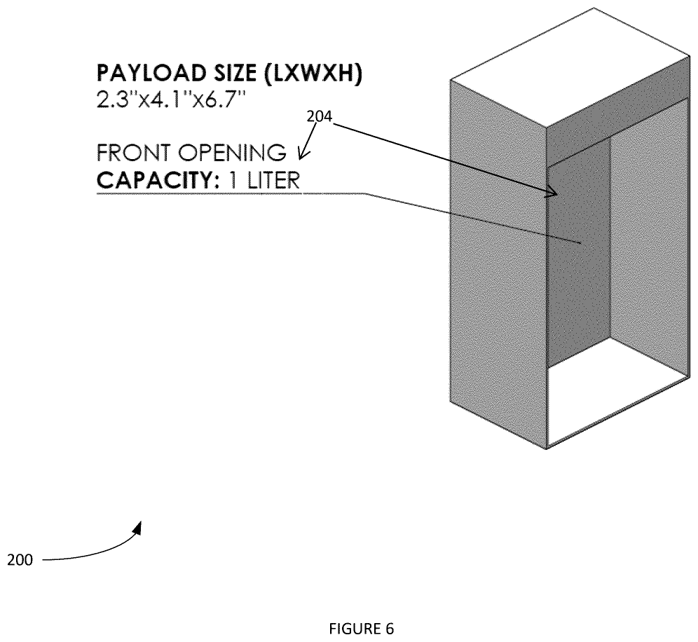

FIG. 6-9 illustrate various example views of an aluminum cooling chamber portable unit 200, according to some embodiments. Aluminum cooling chamber portable unit 200 can be the internal cooling/heating system of portable temperature-controlled enclosure 100.

Aluminum cooling chamber portable unit 200 of portable temperature-controlled enclosure 100 comprises a sophisticated thermoelectric cooling mechanism wherein electrical power is transmitted through a strategically positioned semiconductor chip 202 mounted at a calculated angular orientation relative to the aluminum front-loaded payload chamber 204. The semiconductor chip 202 incorporates a material combination wherein electrons traverse between different semiconductor elements, creating an energy absorption effect at the material junction interfaces. This energy absorption phenomenon, occurring at the precise locations where the material composition transitions, facilitates the cooling process through electron mobility differentials between the semiconductor materials.

The thermal management system utilizes direct thermal coupling between the semiconductor chip 202 and an aluminum front-loaded payload chamber 204, whereby the energy absorption at the material junctions actively extracts heat from the payload area through the aluminum wall interface. The extracted thermal energy is subsequently transferred to a closed-loop cooling system 206 comprising fluid-carrying pipes directly coupled to the posterior surface of the semiconductor chip (e.g. can include a heat sink system). The cooling loop 206 employs either water or antifreeze as the working fluid, circulating through an engineered pipe network via an integrated pump mechanism.

The system's thermal circuit can be completed through a fan-assisted heat exchanger configuration 214 (e.g. with fan 208, air-flow vent 214, etc.), wherein the heated working fluid from the cooling loop 206 is actively cooled before being recirculated through the system. The angular mounting of the semiconductor chip, deliberately oriented at a calculated angle rather than perpendicular to the payload chamber, achieves enhanced cooling distribution by optimizing the radius of coolness spread and increasing the effective surface area coverage. This angular configuration demonstrably improves the speed and uniformity of temperature distribution compared to traditional perpendicular mounting arrangements.

The thermal control system can operate in a dual-power configuration, initially utilizing wall power for the cooldown phase until the target temperature (typically 2° C.) is achieved, at which point the system transitions to battery power through a lithium polymer battery assembly capable of maintaining temperature control for 72 hours of autonomous operation. The internal configuration includes various front-loading variants (e.g. via front-side opening 212, etc.) while maintaining identical operational principles, with the semiconductor chip positioning optimized for each configuration to maximize cooling efficiency through enhanced radial distribution patterns.

The angular orientation of the semiconductor chip 202 relative to the payload chamber wall facilitates superior thermal spreading characteristics. The cooling effect disperses in a radial pattern rather than traditional linear distribution, resulting in more efficient coverage of the payload surface area and accelerated temperature equalization throughout the chamber.

This geometric optimization of the semiconductor chip 202 placement enables the system to achieve more comprehensive thermal coverage compared to conventional perpendicular mounting configurations, as the angular positioning creates an expanded radius of cooling influence that enhances the overall heat absorption efficiency of the system.

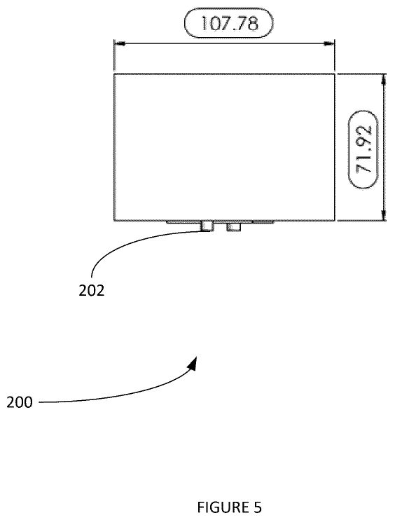

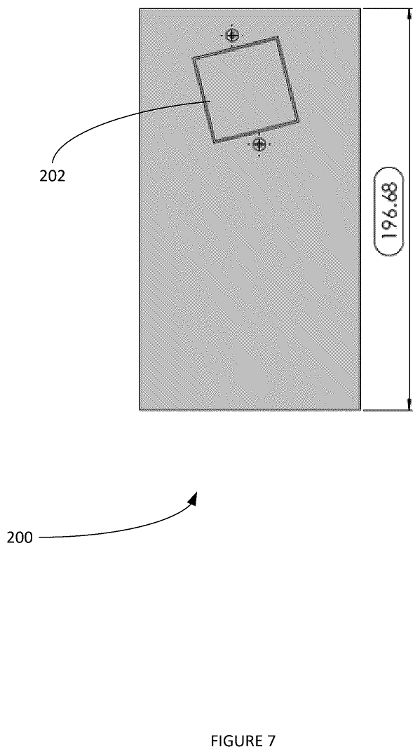

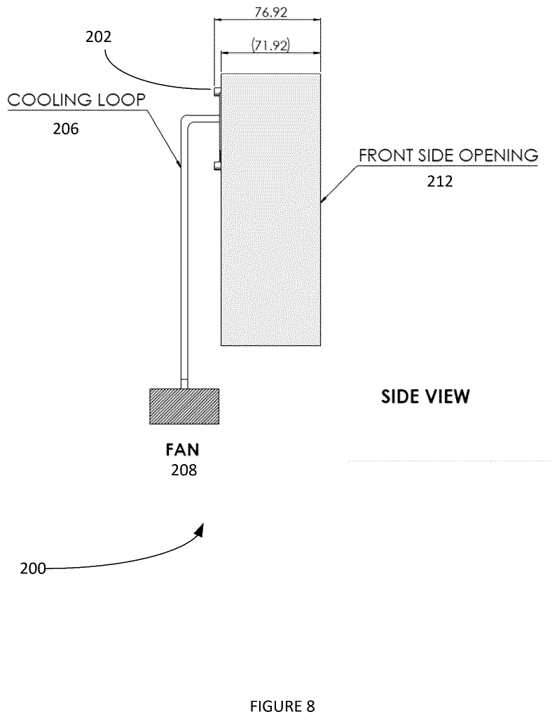

FIG. 5-8 illustrate various example views of an aluminum cooling chamber portable unit, according to some embodiments. FIG. 5 illustrates a top-view of aluminum cooling chamber portable unit, according to some embodiments. FIG. 6 illustrates a isometric-view of aluminum cooling chamber portable unit, according to some embodiments. FIG. 7 illustrates a rear-view of aluminum cooling chamber portable unit, according to some embodiments. FIG. 8 illustrates a side-view of aluminum cooling chamber portable unit, according to some embodiments.

### Example Computer Architecture and Systems

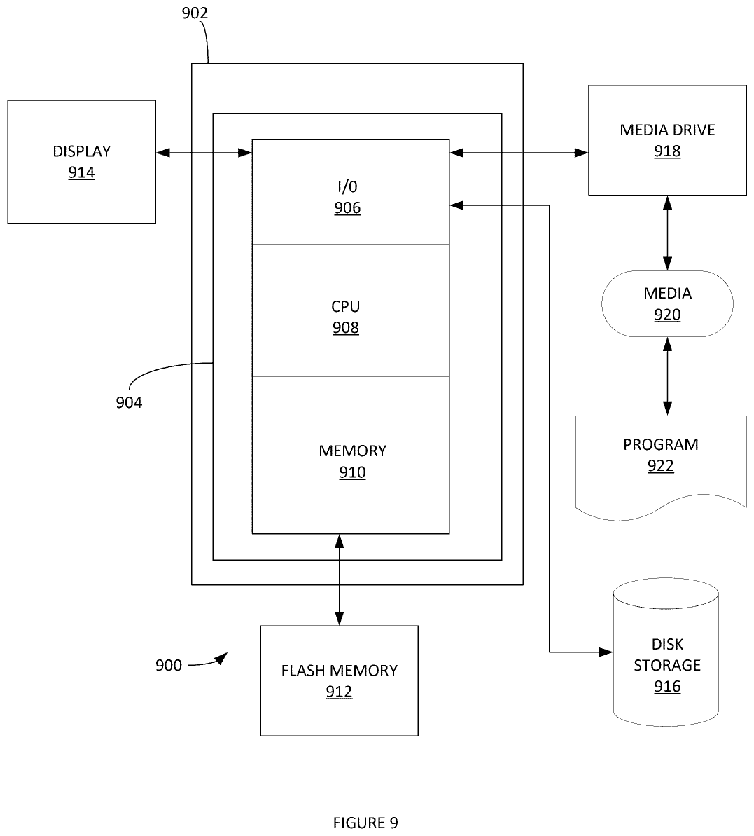

FIG. 9 depicts an exemplary computing system 900 that can be configured to perform any one of the processes provided herein. In this context, computing system 900 may include, for example, a processor, memory, storage, and I/O devices (e.g., monitor, keyboard, disk drive, Internet connection, etc.). However, computing system 900 may include circuitry or other specialized hardware for carrying out some or all aspects of the processes. In some operational settings, computing system 900 may be configured as a system that includes one or more units, each of which is configured to carry out some aspects of the processes either in software, hardware, or some combination thereof.

FIG. 9 depicts computing system 900 with a number of components that may be used to perform any of the processes described herein. The main system 902 includes a motherboard 904 having an I/O section 906, one or more central processing units (CPU) 908, and a memory section 910, which may have a flash memory card 912 related to it. The I/O section 906 can be connected to a display 914, a keyboard and/or other user input (not shown), a disk storage unit 916, and a media drive unit 918. The media drive unit 918 can read/write a computer-readable medium 920, which can contain programs 922 and/or data. Computing system 900 can include a web browser. Moreover, it is noted that computing system 900 can be configured to include additional systems in order to fulfill various functionalities. Computing system 900 can communicate with other computing devices based on various computer communication protocols such a Wi-Fi, Bluetooth® (and/or other standards for exchanging data over short distances includes those using short-wavelength radio transmissions), USB, Ethernet, cellular, an ultrasonic local area communication protocol, etc.

Thermo-electric cooler pump can be managed by a computing system in the portable smart refrigerator. The computing system can be coupled with an exterior display. Exterior display can display various parameters (e.g. temperature, batter power, etc.) of the portable smart refrigerator. Computing system can also be coupled with various other systems such as, inter alia: temperature sensors, digital clocks, Wi-Fi systems, etc.

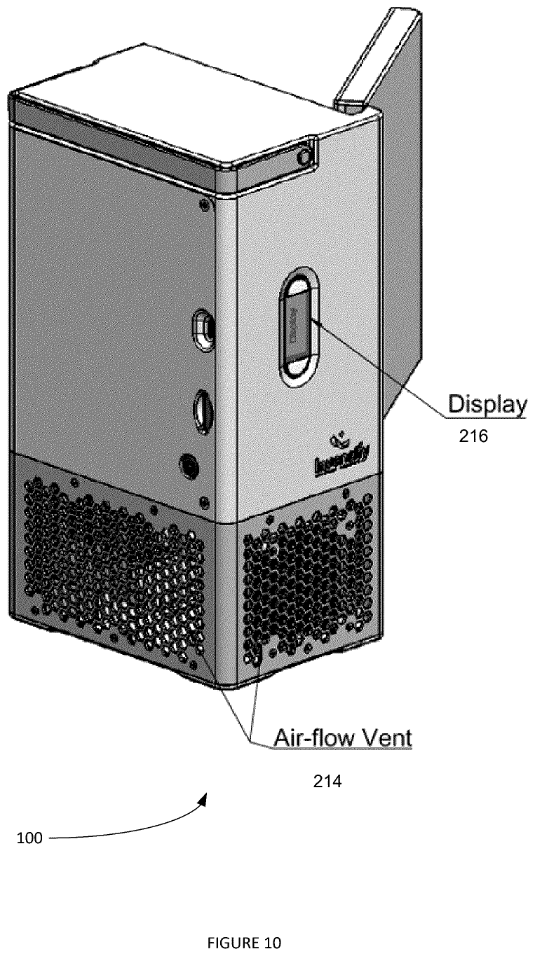

FIG. 10 a view of a display 216 integrated into a portable front-loaded temperature-controlled enclosure, according to some embodiments.

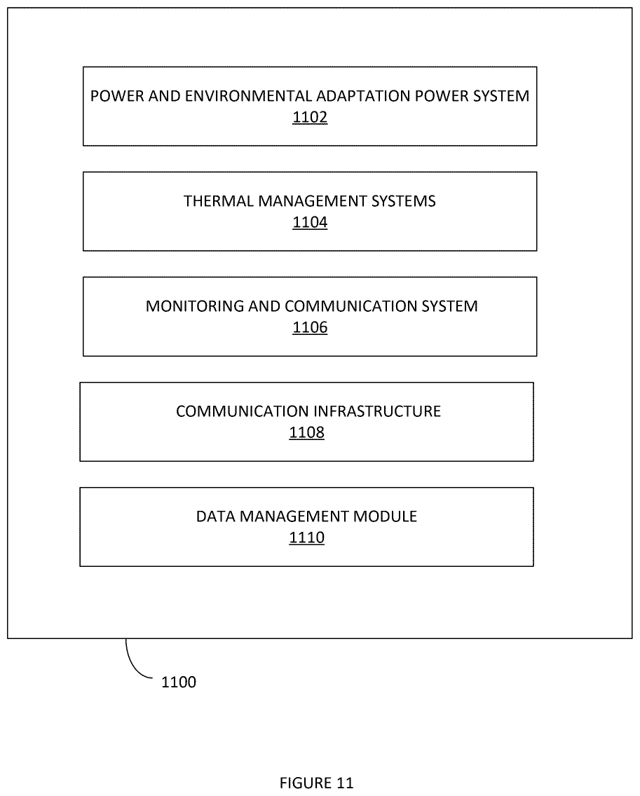

FIG. 11 illustrates a logical view 1100 of a portable front-loaded temperature-controlled enclosure, according to some embodiments. Power and environmental adaptation power system 1102. The front-loading portable temperature-controlled enclosure 100 includes an input compatibility, by way of example of a Universal AC power (110V/220V) and an integrated charging system. Thermal management systems 1104 manage the temperature of front-loading portable temperature-controlled enclosure 100. Thermal management systems 110 of the front-loading portable temperature-controlled enclosure 100 can maintain 2-8° C. in both hot and cold ambient conditions. Monitoring and communication system 1106 for temperature monitoring. Real-time temperature tracking is implemented across continuous internal temperature measurement. The front-loading portable temperature-controlled enclosure 100 includes a digital display for current temperature indication. The front-loading portable temperature-controlled enclosure 100 includes an alert system for temperature deviations. The front-loading portable temperature-controlled enclosure 100 includes a communication infrastructure 1108 that can include an integrated LTE module with SIM card and/or GPS location tracking capability. The front-loading portable temperature-controlled enclosure 100 can perform data transmission intervals (e.g. at 4-5 minutes. The front-loading portable temperature-controlled enclosure 100 also includes cloud connectivity for remote monitoring. A backup SD card storage system can be included for offline data logging. The front-loading portable temperature-controlled enclosure 100 includes a Data Management module 1110 for continuous temperature logging and location tracking and recording.

In one embodiment, an portable temperature-controlled front-loaded enclosure that utilizes solid-state cooling technology, specifically designed for maintaining precise temperatures during transport and storage of temperature-sensitive materials. At its core, the device features a precision-engineered aluminum payload chamber with a 1-liter capacity and a front-loading configuration, measuring 107.78 mm×119.92 mm×166.84 mm. The system's innovative cooling mechanism employs a semiconductor chip mounted at a calculated angular orientation relative to the aluminum chamber wall, which creates an optimized radial cooling pattern for enhanced temperature distribution. This design eliminates the need for traditional cooling infrastructure components like compressors or refrigerant gases.

The enclosure incorporates sophisticated thermal management systems, including a closed-loop cooling system with fluid-carrying pipes and a fan-assisted heat exchanger configuration for efficient heat dissipation. The device operates through a dual-power system, utilizing both wall power (110V/220V) and battery power, with the capability to maintain temperatures between 2-8° C. for up to 72 hours on battery power alone. Advanced monitoring features include real-time temperature tracking, GPS location monitoring, and cloud connectivity for remote monitoring, all managed through an integrated control system that provides automated temperature deviation compensation and alerts. The system can achieve its target temperature of 2° C. within a 2-hour initialization period and maintains temperature stability across varied environmental conditions, making it particularly suitable for medical and biological applications requiring precise temperature control.

### CONCLUSION

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g., embodied in a machine-readable medium).

In addition, it can be appreciated that the various operations, processes, and methods disclosed herein can be embodied in a machine-readable medium and/or a machine accessible medium compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium.

What is claimed by United States patent:

1. A portable front-loaded temperature-controlled enclosure comprising:
a front-loaded aluminum payload chamber;
a semiconductor chip mounted at an angular orientation relative to a wall of the front-loaded payload chamber;
a closed-loop cooling system thermally coupled to the semiconductor chip;
a power system configured to provide both wall power operation and battery-powered operation; and
a control system configured to maintain a target temperature within the front-loaded payload chamber.

2. The portable temperature-controlled enclosure of claim 1, wherein the semiconductor chip is mounted at an angle between 15 and 20 degrees relative to the front-loaded payload chamber wall to create a radial cooling pattern for enhanced temperature distribution.

3. The portable temperature-controlled enclosure of claim 1, wherein the closed-loop cooling system comprises:
fluid-carrying pipes directly coupled to a posterior surface of the semiconductor chip;
a working fluid comprising either water or antifreeze;
an integrated pump mechanism; and
a fan-assisted heat exchanger.

4. The portable temperature-controlled enclosure of claim 1, wherein the power system comprises:
a lithium polymer battery assembly configured to provide 72 hours of autonomous operation;
universal AC power input compatibility for 110V and 220V; and
intelligent power switching circuitry for transitioning between wall power and battery power.

5. The portable temperature-controlled enclosure of claim 1, wherein the control system comprises:
temperature sensors for continuous monitoring;
an integrated LTE module with SIM card;
GPS location tracking capability; and
local data storage on an SD card.

6. The portable temperature-controlled enclosure of claim 1, wherein the front-loaded payload chamber comprises:
a front-loading configuration;
an internal volume of one liter;
dimensions of 107.78 mm×119.92 mm×166.84 mm; and
a specialized heat-absorbing material combined with aluminum.

7. The portable temperature-controlled enclosure of claim 1, further comprising a thermal interface between the semiconductor chip and front-loaded payload chamber wall, the thermal interface comprising:
a high thermal conductivity compound;
controlled thickness application;
full surface coverage verification; and
a spring-loaded mechanism maintaining 30-40 PSI mounting pressure.

8. The portable temperature-controlled enclosure of claim 1, wherein the control system is configured to:
achieve initial cooldown to 2° C. within 2 hours;
maintain temperature between 2-8° C.;
operate in both standard cooling and winter heating modes; and
provide automated cooling bursts for temperature deviation compensation.

9. The portable temperature-controlled enclosure of claim 1, wherein the semiconductor chip comprises:
multiple semiconductor junctions arranged in an optimized pattern;
direct aluminum interface for maximum thermal conductivity;
energy absorption at material boundaries through electron transition; and
strategic thermal junction placement for uniform cooling.

10. The portable temperature-controlled enclosure of claim 1, further comprising:
real-time temperature and location tracking;
wireless data transmission at 4-5 minute intervals;
cloud connectivity for remote monitoring;
automated alert generation for temperature deviations; and
data logging with offline backup capability.
